(19) United States
(12) Patent Application Publication
(10) Pub. No.: US 2008/0251698 A1
(43) Pub. Date: Oct. 16, 2008

(54) SEMICONDUCTOR OPTICAL RECEIVER MODULE

(75) Inventors: Yusuke KURIHARA, Kanagawa (JP); Kazuhiro MITAMURA, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 11/864,632

(22) Filed: Sep. 28, 2007

(30) Foreign Application Priority Data
Oct. 19, 2006 (JP) 2006-285012

(51) Int. Cl. H01L 27/146

(52) U.S. Cl. 250/214 A; 257/E27.13

(57) ABSTRACT

There is provided a semiconductor optical receiver module that performs efficient heat dissipation, without incurring an increase in cost. The semiconductor optical receiver module includes a substrate provided on a package, a semiconductor photodetector provided on the substrate, a chip capacitor provided on the substrate, and a preamp IC provided on the package, without the intermediation of the substrate.

This application is based on Japanese patent application No.2006-285012, the content of which is incorporated hereinto by reference.

### BACKGROUND

1. Technical Field

The present invention relates to a semiconductor optical receiver module.

2. Related Art

The ongoing progress in speed and capacity of communication is creating growing demand for smaller dimensions and lower cost of optical modules. In the optical modules of reduced dimensions, heat generated by the semiconductor circuit is prone to remain inside the module, and hence measures have to be taken to improve its heat dissipation performance, to thereby prevent the operation temperature range from becoming narrower. In addition, the expansion of the optical communication market has been forcing the optical modules to be less and less expensive.

FIG. 2 is a perspective view showing a semiconductor optical receiver module disclosed in JP-A No.H07-312430. In the semiconductor optical receiver module 100, a substrate 102 is mounted on a package 101. On the substrate 102, a semiconductor photodetector 103, a capacitor 104, and a preamp IC 105 are provided. The capacitor 104 is a chip capacitor, and is connected between a ground (GND) and a power source for the semiconductor photodetector 103 and the preamp IC 105, so as to cut a noise of the power source.

FIG. 3 is a perspective view showing another semiconductor optical receiver module disclosed in JP-A No.H07-312430. In the semiconductor optical receiver module 200, a semiconductor photodetector 203, a capacitor 204, and a preamp IC 205 are mounted on a package 201. The semiconductor optical receiver module 200 does not include the substrate for mounting the components thereon, but the preamp IC 205 is mounted directly on the package 201. The capacitor 204 is a parallel plate capacitor, and is connected between a ground (GND) and a power source for the semiconductor photodetector 203 and the preamp IC 205, so as to cut a noise of the power source. The semiconductor photodetector 203 is mounted on the capacitor 204.

Prior art related to the present invention includes JP-A No.2003-289149, in addition to JP-A No.H07-312430.

[Patented document 1] JP-A No.H07-312430

[Patented document 2] JP-A No.2003-289149

In the semiconductor optical receiver module 100 shown in FIG. 2, however, the preamp IC 105 is mounted on the substrate 102 made on a ceramic or the like, which suppresses the heat generated by the preamp IC 105, from being efficiently released through the package 101. The operation temperature range of the preamp IC is limited by a temperature on the circuit. Accordingly, failure in efficiently releasing the heat generated by the preamp IC leads to a temperature increase of the preamp IC, thereby narrowing the operation temperature range.

In contrast, in the semiconductor optical receiver module 200 shown in FIG. 3, the preamp IC 205 is mounted directly on the package 201, and hence sufficient heat dissipation can be secured. However, the parallel plate capacitor 204, employed as a bypass capacitor, is an expensive component, which naturally leads to an increase in cost.

### SUMMARY

In one embodiment, there is provided a semiconductor optical receiver module comprising a substrate provided on a package; a semiconductor photodetector provided on the substrate; a chip capacitor provided on the substrate; and a preamp provided on the package, without intermediation of the substrate.

In the semiconductor optical receiver module thus constructed, the preamp is mounted on the package without the intermediation of the substrate. Accordingly, unlike the semiconductor optical receiver module shown in FIG. 2, the heat generated by the preamp can be efficiently released through the package. Besides, since the chip capacitor which is inexpensive is employed as the capacitor, the increase in cost can be suppressed, unlike the case of the semiconductor optical receiver module shown in FIG. 3.

Thus, the present invention provides a semiconductor optical receiver module that performs efficient heat dissipation, without incurring an increase in cost.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view showing a semiconductor optical receiver module according to an embodiment of the present invention;

FIG. 2 is a perspective view showing a conventional semiconductor optical receiver module; and

FIG. 3 is a perspective view showing another conventional semiconductor optical receiver module.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereunder, an exemplary embodiment of a semiconductor optical receiver module according to the present invention will be described referring to the accompanying drawings. In all the drawings, same constituents are given the same numerals, and the description thereof will not be repeated.

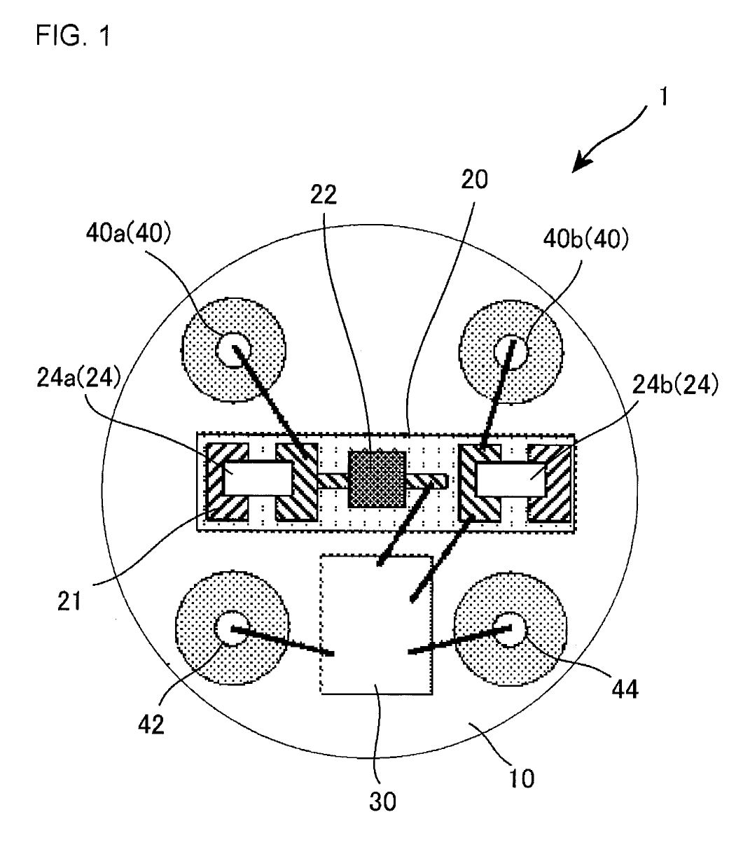

FIG. 1 is a plan view showing a semiconductor optical receiver module according to an embodiment of the present invention. The semiconductor optical receiver module 1 includes a substrate 20 provided on a package 10, a semiconductor photodetector 22 provided on the substrate 20, a chip capacitor 24 provided on the substrate 20, and a preamp IC 30 provided on the package 10, without the intermediation of the substrate 20.

The package 10 may be a glass CAN-PKG, for example. On the package, the substrate 20 and the preamp IC 30 are mounted. On the substrate 20 a conductor pattern 21 is provided. On the substrate 20, the semiconductor photodetector 22 and the chip capacitor 24 are mounted. In this embodiment, only the semiconductor photodetector 22 and the chip capacitor 24 are provided on the substrate 20. The semiconductor photodetector 22 and the chip capacitor 24 are respectively located in different regions on the substrate 20. The semiconductor photodetector 22 may be a back-incidence type photodiode. The preamp IC 30 is directly mounted on the package 10. In other words, while the semiconductor photodetector 22 and the chip capacitor 24 are provided on the package 10 via the substrate 20, the preamp IC 30 is provided on the package 10 without the substrate 20 interposed therebetween.

The semiconductor optical receiver module 1 further includes a power supply terminal 40 provided on the package 10. The power supply terminal 40 includes a power supply terminal 40a (first power supply terminal) that supplies a voltage to the semiconductor photodetector 22, and a power supply terminal 40b (second power supply terminal) that supplies a voltage to the preamp IC 30. The chip capacitor 24 is connected between each of the power supply terminals 40a, 40b and a ground, so as to reduce a noise of the power source. To be more detailed, the chip capacitor 24 includes a chip capacitor 24a (first chip capacitor) connected to the power supply terminal 40a and a chip capacitor 24b (second chip capacitor) connected to the power supply terminal 40b. The chip capacitors 24a, 24b are aligned with the semiconductor photodetector 22 placed therebetween. The chip capacitor 24a is connected to the semiconductor photodetector 22 via the conductor pattern 21.

Here, the conductor pattern 21 includes a pattern for the ground and a pattern for the power supply terminal, out of which the former is electrically connected to the upper surface of the package 10, while the latter is not electrically connected thereto. In this embodiment the pattern for the ground is electrically connected to the upper surface of the package 10 through a via formed in the substrate 20. Alternatively, the electrical connection may be provided by lateral metallization. In other words, the pattern for the ground and the upper surface of the package 10 may be electrically connected via the metallized lateral face of the substrate 20.

In the semiconductor optical receiver module 1, upon applying a voltage to the power supply terminal 40a for the semiconductor photodetector 22 and the power supply terminal 40b for the preamp IC 30, an optical signal incident upon the semiconductor photodetector 22 is converted into an electrical signal, and is input as a voltage signal from output terminals 42, 44. In this process, the chip capacitor 24a and the chip capacitor 24b respectively serve as a noise filter of the power source for the semiconductor photodetector 22 and a noise filter of the power source for the preamp IC 30.

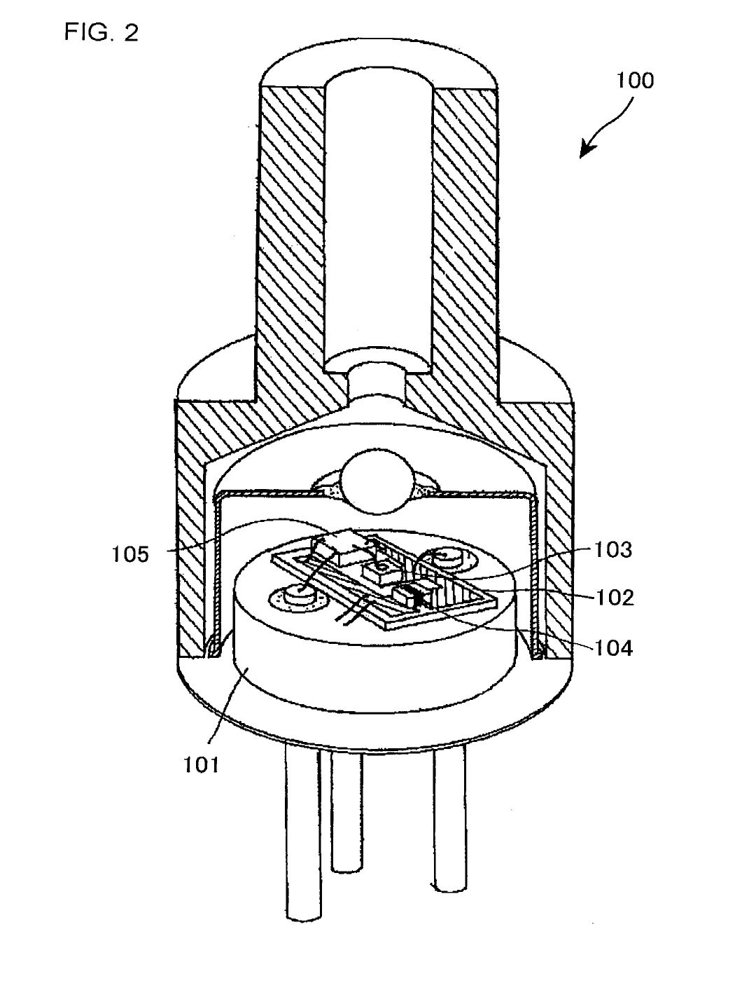

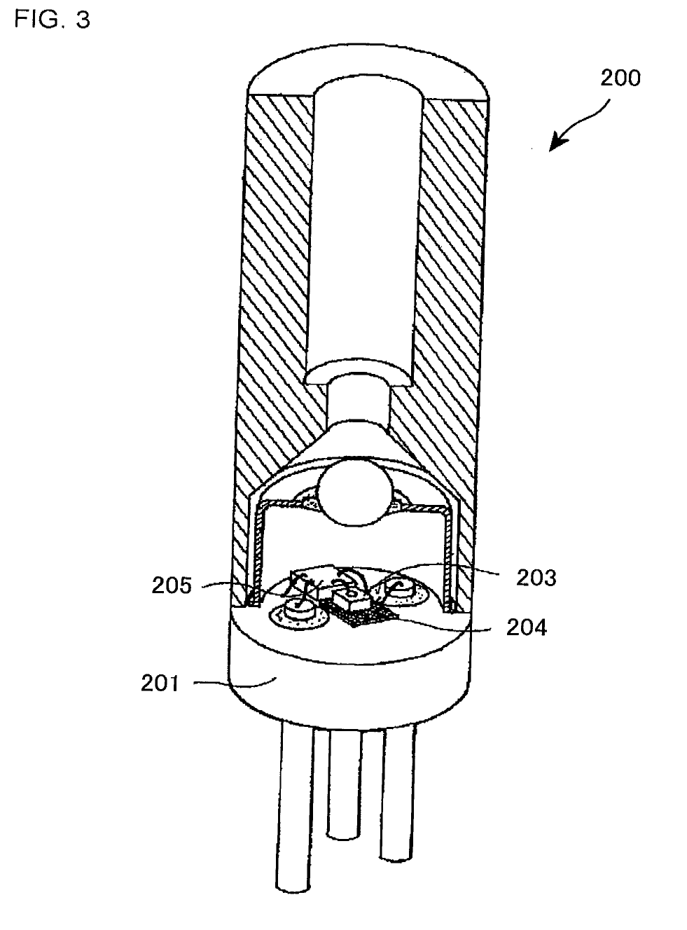

The foregoing embodiment provides the following advantageous effects. In the semiconductor optical receiver module 1, the preamp IC 30 is mounted on the package 10 without the intermediation of the substrate 20. Accordingly, unlike the semiconductor optical receiver module 100 shown in FIG. 2, the heat generated by the preamp IC 30 can be efficiently released through the package 10. Besides, since the chip capacitors 24a, 24b, which are inexpensive, are employed as the capacitor, the increase in cost can be suppressed, unlike the case of the semiconductor optical receiver module 200 shown in FIG. 3. Consequently, the semiconductor optical receiver module 1 is capable of performing efficient heat dissipation, without incurring an increase in cost. This embodiment provides an inexpensive photodetector module that can prevent degradation in temperature characteristic.

Meanwhile, the presence of the substrate 20 might incur an increase in cost, compared with a module that does not include a substrate. However, in the case of employing a back-incidence type element as the semiconductor photodetector 22, a substrate to mount the photodetector thereon is anyway indispensable. Therefore, the increase in cost can only be minimal, if any.

It is apparent that the present invention is not limited to the above embodiment, and may be modified and changed without departing from the scope and spirit of the invention. For example, although the preamp IC 30 is directly mounted on the package 10 in the foregoing embodiment, a material other than the substrate 20 may be interposed between the package 10 and the preamp IC 30. In this case, it is preferable that the material is superior to the substrate 20 in heat dissipation.

What is claimed is:

1. A semiconductor optical receiver module, comprising:
a substrate provided on a package;
a semiconductor photodetector provided on said substrate;
a chip capacitor provided on said substrate; and
a preamp provided on said package, without intermediation of said substrate.

2. The semiconductor optical receiver module according to claim 1, further comprising:
a power supply terminal provided on said package;
wherein said chip capacitor is connected between said power supply terminal and a ground, so as to reduce a noise of a power source.

3. The semiconductor optical receiver module according to claim 2,
wherein said power supply terminal includes a first power supply terminal that supplies a voltage to said semiconductor photodetector, and a second power supply terminal that supplies a voltage to said preamp.

4. The semiconductor optical receiver module according to claim 3,
wherein said chip capacitor includes a first chip capacitor connected between said first power supply terminal and a ground, and a second chip capacitor connected between said second power supply terminal and a ground.

5. The semiconductor optical receiver module according to claim 4,
wherein said first and said second chip capacitor are aligned, with said semiconductor photodetector placed therebetween.

6. The semiconductor optical receiver module according to claim 1,
wherein said semiconductor photodetector is of a back-incidence type.
